(19) United States
(12) Patent Application Publication
(10) Pub. No.: US 2026/0002246 A1
(43) Pub. Date: Jan. 1, 2026

(54) DEPOSITION MASK, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventor: Jin Yong LEE, Yongin-si (KR)

(21) Appl. No.: 19/068,183

(22) Filed: Mar. 3, 2025

(30) Foreign Application Priority Data
Jun. 27, 2024 (KR) 10-2024-0084561

(51) Int. Cl. C23C 14/04; G02B 27/01; H10K 59/12; H10K 71/16

(52) U.S. Cl. CPC C23C 14/042; G02B 27/0172; H10K 59/1201; H10K 71/166; G02B 2027/0178

(57) ABSTRACT

A deposition mask includes a mask frame with a cell opening defined therein and a membrane disposed on the mask frame. The membrane includes a cell region disposed on the cell opening, a plurality of pixel openings is defined in the cell region to be connected to the cell opening, and an interfacial residual stress between the mask frame and the membrane is in a range of about −30 MPa to about 30 MPa.

This application claims priority to Korean Patent Application No. 10-2024-0084561, filed on Jun. 27, 2024, and all the benefits accruing therefrom under 35 U.S.C. § 119, the content of which in its entirety is herein incorporated by reference.

### BACKGROUND

### 1. Field

The disclosure relates to a deposition mask, a method of manufacturing the same, and an electronic device manufactured by using the same.

### 2. Description of the Related Art

Wearable devices that have the form of glasses or a helmet and form a focus at a distance close to user's eyes in front of the user's eyes have been developed. For example, the wearable device may be a head mounted display (HMD) device or augmented reality (AR) glasses. Such a wearable device may provide an AR screen or a virtual reality (VR) screen to a user.

The wearable device such as the HMD device or the AR glasses is desired to display specifications of about 3,000 pixels per inch (PPI) or higher to allow the user to use the wearable device for a long time without dizziness. To this end, an organic light emitting diode on silicon (OLEDoS) technology, which is used in a small organic light emitting display device having a high resolution, has emerged. The OLEDoS technology is a technology that disposes organic light emitting diodes (OLEDs) on a semiconductor wafer on which complementary metal oxide semiconductor (CMOS) elements are disposed.

### SUMMARY

In order to manufacture a display panel having a high resolution of about 3000 PPI or higher, a deposition mask having a high resolution is desired. For example, the deposition mask may be manufactured by forming a membrane having a plurality of pixel openings on a substrate such as a silicon wafer and partially etching the substrate to form cell openings exposing the pixel openings. However, during the manufacture of the deposition mask, warpage may occur in the deposition mask due to a difference in coefficient of thermal expansion between the substrate and the membrane, residual stress of the membrane, and the like.

Embodiments of the disclosure provide an improved deposition mask capable of reducing warpage, a method of manufacturing the deposition mask, and an electronic device manufactured by using the deposition mask.

However, embodiments of the disclosure are not limited to those set forth herein. The above and other embodiments of the disclosure will become more apparent to one of ordinary skill in the art to which the disclosure pertains by referencing the detailed description of the disclosure given below.

According to one or more embodiments of the disclosure, a deposition mask may include a mask frame with a cell opening defined therein and a membrane disposed on the mask frame. In such embodiments, the membrane includes a cell region disposed on the cell opening, a plurality of pixel openings may be defined in the cell region to be connected to the cell opening, and an interfacial residual stress between the mask frame and the membrane may be in a range about −30 megapascals (MPa) to about 30 MPa.

In an embodiment, the mask frame may include silicon, and the membrane may include silicon nitride.

In an embodiment, the membrane may have a silicon content higher than a silicon content of stoichiometric silicon nitride.

In an embodiment, a nitrogen content of the membrane may be constant in a thickness direction of the membrane.

In an embodiment, a nitrogen content of the membrane may gradually increase from an interface between the mask frame and the membrane in a thickness direction of the membrane.

In an embodiment, the membrane may include a plurality of silicon nitride films stacked on the mask frame.

In an embodiment, a nitrogen content of the silicon nitride films may stepwise increase from an interface between the mask frame and the membrane in a direction in which the silicon nitride films are stacked.

In an embodiment, a silicon content of the silicon nitride films may stepwise decrease from an interface between the mask frame and the membrane in a direction in which the silicon nitride films are stacked.

In an embodiment, an uppermost silicon nitride film of the silicon nitride films may have a silicon content higher than a silicon content of stoichiometric silicon nitride.

According to one or more embodiments of the disclosure, a method of manufacturing a deposition mask includes forming an inorganic film on a substrate, forming a plurality of pixel openings by patterning the inorganic film, where the pixel openings exposes the substrate, and forming cell openings by patterning the substrate, where the cell openings is connected to the pixel openings. In such embodiments, an interfacial residual stress between the substrate and the inorganic film may be in a range about −30 MPa to about 30 MPa.

In an embodiment, the substrate may include silicon, and the inorganic film may include silicon nitride and may be formed through a chemical vapor deposition process.

In an embodiment, the chemical vapor deposition process may be performed under a pressure in a range of about 210 millitorr (mTorr) to about 250 mTorr and a temperature in a range of about 800° C. to about 850° C.

In an embodiment, the inorganic film may be formed by a reaction between a first source gas including silicon and a second source gas including nitrogen, and a supply flow rate ratio between the first source gas and the second source gas may be controlled to be in a range of about 10:1 to about 10:1.7.

In an embodiment, a dichlorosilane (DCS) gas may be used as the first source gas, and an ammonia gas may be used as the second source gas.

In an embodiment, the inorganic film may have a silicon content higher than a silicon content of stoichiometric silicon nitride, and a nitrogen content of the inorganic film may be constant in a thickness direction of the inorganic film.

In an embodiment, the supply flow rate ratio between the first source gas and the second source gas may be gradually changed from about 10:1 to about 10:1.7 during the chemical vapor deposition process.

In an embodiment, a silicon content of the inorganic film may gradually decrease from an interface between the substrate and the inorganic film in a thickness direction of the inorganic film, and a nitrogen content of the inorganic film may gradually increase from the interface between the substrate and the inorganic film in the thickness direction of the inorganic film.

In an embodiment, the inorganic film may include a plurality of silicon nitride films stacked on the substrate, and the silicon nitride films may be formed by stepwise changing the supply flow rate ratio between the first source gas and the second source gas from about 10:1 to about 10:1.7 during the chemical vapor deposition process.

In an embodiment, a silicon content of the silicon nitride films may stepwise decrease from an interface between the substrate and the inorganic film in a direction in which the silicon nitride films are stacked, and a nitrogen content of the silicon nitride films may stepwise increase from the interface between the substrate and the inorganic film in the direction in which the silicon nitride films are stacked.

In an embodiment, an uppermost silicon nitride film of the silicon nitride films may have a silicon content higher than a silicon content of stoichiometric silicon nitride.

According to one or more embodiments of the disclosure, an electronic device includes a display panel including a substrate and a plurality of light-emitting layers formed on the substrate, where the light-emitting layers are formed by using a deposition mask. In such embodiments, the deposition mask includes a mask frame with a cell opening defined therein, and a membrane disposed on the mask frame. In such embodiments, the membrane may include a cell region disposed on the cell opening, a plurality of pixel openings is defined in the cell region to be connected to the cell opening, and an interfacial residual stress between the mask frame and the membrane may be in a range about −30 MPa to about 30 MPa.

According to embodiments of the disclosure as described above, the interfacial residual stress between a mask frame and a membrane is in a range of about −30 MPa to about 30 MPa, which is very small, and thus, warpage of a deposition mask may be substantially reduced or effectively prevented.

Other features and embodiments may be apparent from the following detailed description and the drawings.

### BRIEF DESCRIPTION OF THE DRAWINGS

The above and other features of embodiments of the disclosure will become more apparent by describing in detail embodiments thereof with reference to the attached drawings, in which:

FIG. 1 is an exploded perspective view illustrating a display device;

FIG. 2 is a block diagram for explaining the display device shown in FIG. 1;

FIG. 3 is an equivalent circuit diagram illustrating an embodiment of a first sub-pixel shown in FIG. 2;

FIG. 4 is a schematic plan view illustrating an embodiment of the display panel shown in FIG. 1;

FIG. 5 is a schematic plan view illustrating an embodiment of the display area shown in FIG. 4;

FIG. 6 is a schematic plan view illustrating another embodiment of the display area shown in FIG. 4;

FIG. 7 is a cross-sectional view illustrating an embodiment of the display panel taken along line I-I′ of FIG. 5;

FIG. 8 is a schematic perspective view illustrating an embodiment of a head mounted display;

FIG. 9 is a schematic exploded perspective view illustrating the head mounted display shown in FIG. 8;

FIG. 10 is a schematic perspective view illustrating another embodiment of a head mounted display;

FIG. 11 is a schematic plan view illustrating a deposition mask according to an embodiment of the disclosure;

FIG. 12 is a schematic plan view illustrating cell regions and a grid region shown in FIG. 11;

FIG. 13 is a schematic cross-sectional view taken along line II-II′ shown in FIG. 12;

FIG. 14 is a schematic cross-sectional view illustrating a deposition mask according to another embodiment of the disclosure;

FIG. 15 is a schematic view illustrating an embodiment of a deposition apparatus including the deposition mask shown in FIGS. 11 to 13 or FIG. 14;

FIGS. 16 to 21 are schematic cross-sectional views illustrating a method of manufacturing a deposition mask according to an embodiment of the disclosure; and

FIG. 22 is a schematic cross-sectional view illustrating a method of manufacturing a deposition mask according to another embodiment of the disclosure.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when an element or a layer is referred to as being “on” another element or layer, it can be directly on the other element or layer, or intervening layers may also be present therebetween. In contrast, when an element is referred to as being “directly on” another element, there are no intervening elements present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

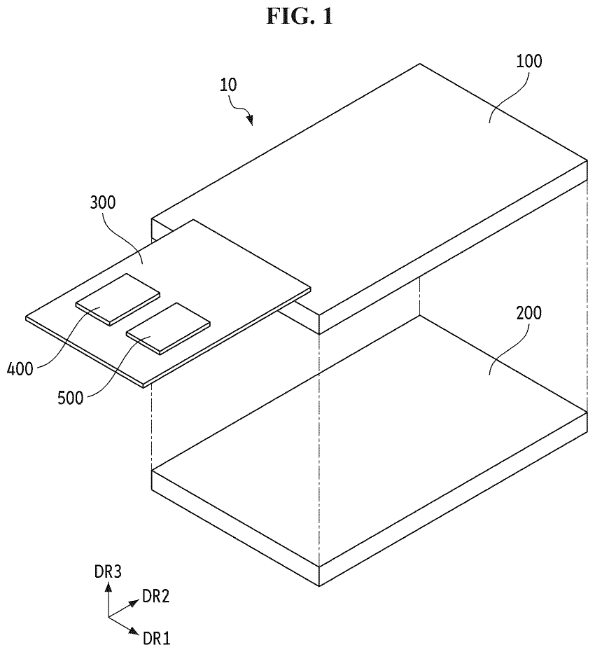

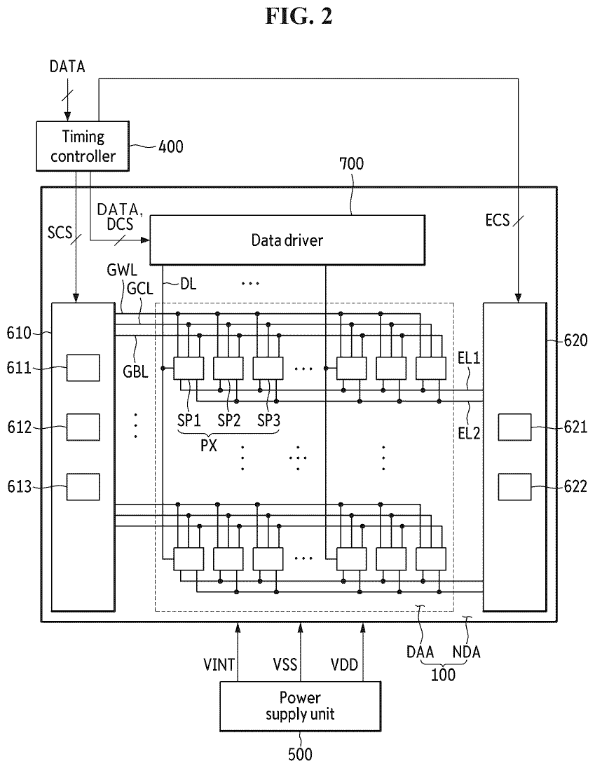

FIG. 1 is an exploded perspective view illustrating a display device. FIG. 2 is a block diagram for explaining the display device shown in FIG. 1.

Referring to FIGS. 1 and 2, an embodiment of a display device 10 may be a device displaying a moving image or a still image. The display device 10 may be applied to portable electronic devices such as a mobile phone, a smartphone, a tablet personal computer (PC), a mobile communication terminal, an electronic organizer, an electronic book, a portable multimedia player (PMP), a navigation system, an ultra mobile PC (UMPC) and the like. For example, the display device 10 may be applied as a display unit of electronic devices such as a television, a laptop, a monitor, a billboard, an Internet-of-Things (IoT) device, and the like. Alternatively, the display device 10 may be applied to electronic devices such as a smart watch, a watch phone, a head mounted display (HMD) for implementing virtual reality and augmented reality, and the like.

In an embodiment, the display device 10 may include a display panel 100, a heat dissipation layer 200, a circuit board 300, a timing control circuit 400, and a power supply circuit 500.

The display panel 100 may have a planar shape similar to a quadrilateral shape. In an embodiment, for example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may correspond to the planar shape of the display panel 100, but the disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. In an embodiment, as shown in FIG. 2, the display panel 100 may be divided into a display area DAA for displaying an image and a non-display area NDA not for displaying an image.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

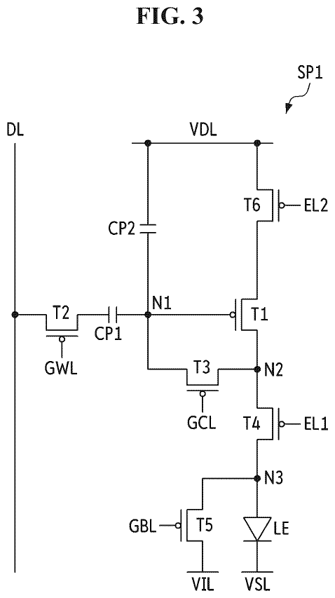

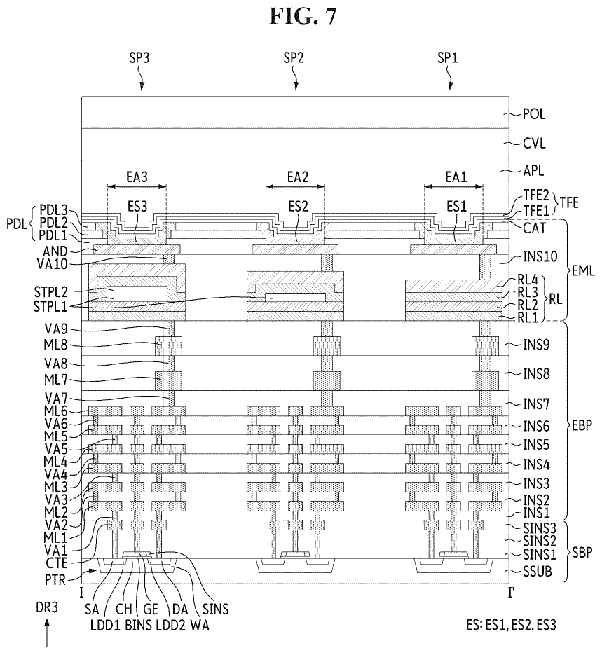

The plurality of pixels PX may include a plurality of sub-pixels SP1, SP2, and SP3. The plurality of sub-pixels SP1, SP2, and SP3 may include a plurality of pixel transistors (see FIG. 3). The plurality of pixel transistors may be formed by a semiconductor process, and may be disposed on a semiconductor substrate SSUB (see FIG. 7). In an embodiment, for example, the plurality of pixel transistors of the data driver 700 may be formed through a complementary metal oxide semiconductor (CMOS) process, but the disclosure is not limited thereto.

Each of the plurality of sub-pixels SP1, SP2, and SP3 may be connected to a corresponding one write scan line GWL among the plurality of write scan lines GWL, a corresponding one control scan line GCL among the plurality of control scan lines GCL, any one bias scan line GBL among the plurality of bias scan lines GBL, a corresponding one first emission control line EL1 among the plurality of first emission control lines EL1, a corresponding one second emission control line EL2 among the plurality of second emission control lines EL2, and a corresponding one data line DL among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. In an embodiment, the plurality of scan transistors and the plurality of light-emitting transistors may be formed on the semiconductor substrate SSUB (see FIG. 7) through a semiconductor process. In an embodiment, for example, the plurality of scan transistors and the plurality of light-emitting transistors may be formed through a CMOS process, but the embodiment of the specification is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals in response to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals in response to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals in response to the emission timing control signal ECS and sequentially output them to the first emission control lines EL1. The second emission control driver 622 may generate second emission control signals in response to the emission timing control signal ECS and sequentially output them to the second emission control lines EL2.

The data driver 700 may include a plurality of data transistors, and the plurality of data transistors may be formed through a semiconductor process, and formed on the semiconductor substrate SSUB (see FIG. 7). In an embodiment, for example, the plurality of data transistors may be formed through a CMOS process, but the disclosure is not limited thereto.

The data driver 700 may receive digital video data DATA and a data timing control signal DCS from the timing control circuit 400. The data driver 700 converts the digital video data DATA into analog data voltages in response to the data timing control signal DCS and outputs the analog data voltages to the data lines DL. In an embodiment, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. Here, the third direction DR3 may be a direction perpendicular to the first direction DR1 and the second direction DR2. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

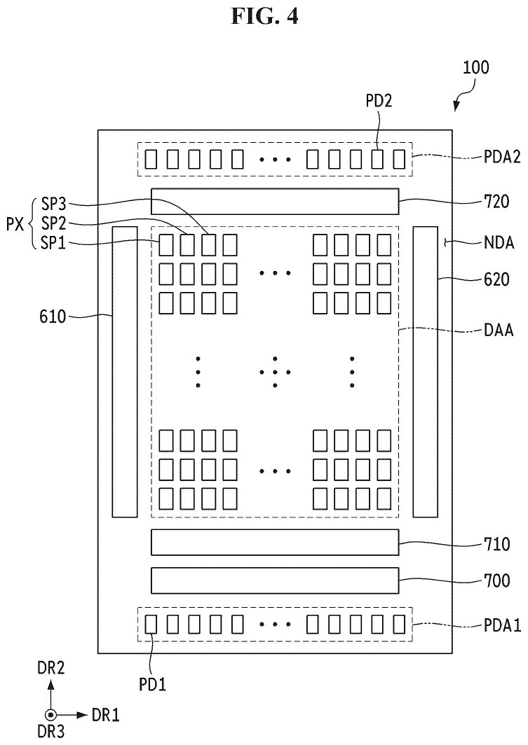

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although FIG. 1 shows the circuit board 300 in an unfolded state for convenience of illustration, the circuit board 300 may be bent. In a state where the circuit board 300 is bent, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

In an embodiment, each of the timing control circuit 400 and the power supply circuit 500 may be formed as an integrated circuit (IC) and attached to one surface of the circuit board 300. In such an embodiment, the scan timing control signal SCS, the emission timing control signal ECS, digital video data DATA, and the data timing control signal DCS of the timing control circuit 400 may be supplied to the display panel 100 through the circuit board 300. In an embodiment, the first driving voltage VSS, the second driving voltage VDD, and the third driving voltage VINT of the power supply circuit 500 may be supplied to the display panel 100 through the circuit board 300.

In another embodiment, for example, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed through a semiconductor process, and formed on the semiconductor substrate SSUB (see FIG. 7). In an embodiment, for example, the plurality of timing transistors and the plurality of power transistors may be formed through a CMOS process, but the disclosure is not limited thereto. Each of the timing control circuit 400 and the power supply circuit 500 may be disposed between the data driver 700 and the first pad portion PDA1 (see FIG. 4).

FIG. 3 is an equivalent circuit diagram illustrating an embodiment of a first sub-pixel shown in FIG. 2.

Referring to FIG. 3, in an embodiment, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In such an embodiment, the first driving voltage VSS may be lower than the third driving voltage VINT, and the second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be substantially proportional to the driving current. The light-emitting element LE may be connected between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer disposed between the first electrode and the second electrode, but the disclosure is not limited thereto. In an embodiment, for example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof based on a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be connected between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be connected between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode. The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be connected between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be connected between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be connected between the first node N1 and the drain electrode of the second transistor T2. The first capacitor CP1 may include one electrode connected to the drain electrode of the second transistor T2 and the other electrode connected to the first node N1.

The second capacitor CP2 may be connected to formed between the gate electrode of the first transistor T1 and the second driving voltage line VDL. The second capacitor CP2 may include one electrode connected to the gate electrode of the first transistor T1 and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). In an embodiment, for example, each of the first to sixth transistors T1 to T6 may be a P-type MOSFET, but the disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 3 illustrates an embodiment where the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, any repetitive detailed description of the equivalent circuit diagram of the second sub-pixel SP2 and the equivalent circuit diagram of the third sub-pixel SP3 will be omitted in the disclosure.

FIG. 4 is a schematic plan view illustrating an embodiment of the display panel shown in FIG. 1.

Referring to FIG. 4, an embodiment of the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, for example, the scan driver 610 may be disposed on one side of the display area DAA in the first direction DR1, and the emission driver 620 may be disposed on the other side of the display area DAA in the first direction DR1. In an embodiment, as shown in FIG. 4, the scan driver 610 may be disposed on the left side of the display area DAA, and the emission driver 620 may be disposed on the right side of the display area DAA. However, the disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on one side of the display area DAA in the second direction DR2. The first pad portion PDA1 may be disposed outside the data driver 700 in the second direction DR2. In an embodiment, as shown in FIG. 4, the first pad portion PDA1 may be disposed closer to the edge of the display panel 100 than the data driver 700.

The second pad portion PDA2 may include a plurality of second pads PD2 corresponding to inspection pads for testing whether the display panel 100 operates normally. The plurality of second pads PD2 may be connected to a jig or probe pins during an inspection process, or may be connected to a circuit board for inspection. The circuit board for inspection may be a printed circuit board including or made of a rigid material or a flexible printed circuit board including or made of a flexible material.

The second pad portion PDA2 may be disposed on the fourth side of the display area DAA. In an embodiment, for example, the second pad portion PDA2 may be disposed on the other side of the display area DAA in the second direction DR2. The second pad portion PDA2 may be disposed outside the second distribution circuit 720 in the second direction DR2. That is, as shown in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. In an embodiment, for example, the first distribution circuit 710 may be disposed on one side of the display area DAA in the second direction DR2. That is, as shown in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. In an embodiment, for example, the second distribution circuit 720 may be disposed on the other side of the display area DAA in the second direction DR2. That is, as shown in FIG. 4, the second distribution circuit 720 may be disposed on the upper side of the display area DAA.

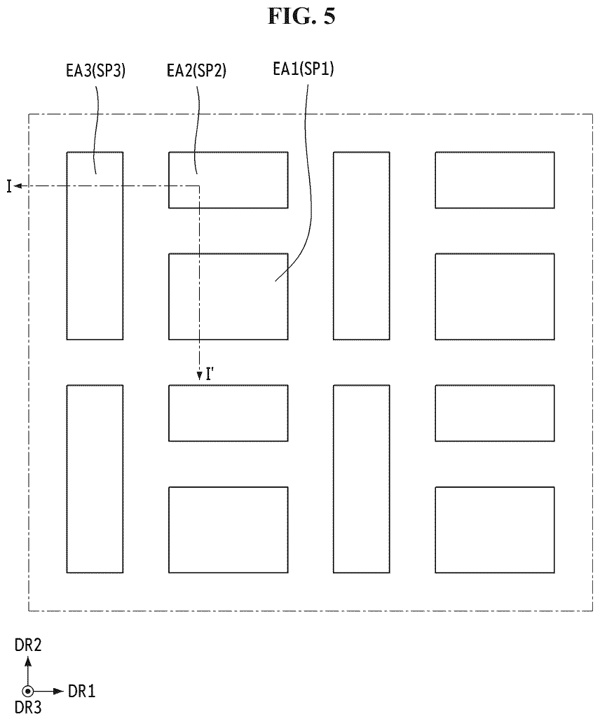

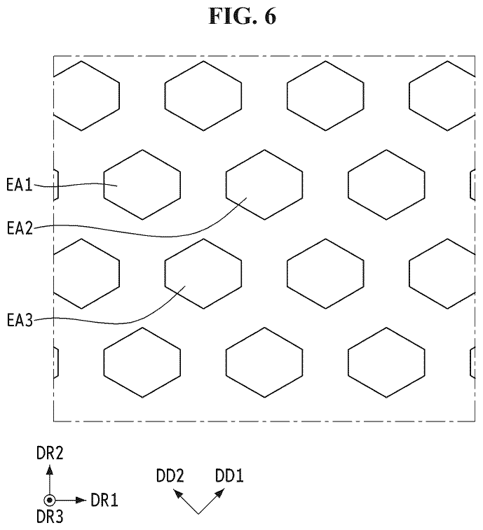

FIG. 5 is a schematic plan view illustrating an embodiment of the display area shown in FIG. 4. FIG. 6 is a schematic plan view illustrating another embodiment of the display area shown in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. In an embodiment, for example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see FIG. 7). In an embodiment, for example, each of the first emission area EA1, the second emission area EA2, and the third emission area EA3 may be an area defined by a first pixel defining film PDL1 (see FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. In an embodiment, for example, the blue wavelength band may be a wavelength band of light whose main peak wavelength is in a range of about 370 nanometers (nm) to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

In another embodiment, for example, as shown in FIG. 6, the first emission area EA1, the second emission area EA2, and the third emission area EA3 may be disposed in a hexagonal structure having a hexagonal shape in plan view. In such an embodiment, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

Although FIGS. 5 and 6 illustrate embodiments where each of the plurality of pixels PX includes the three emission areas EA1, EA2, and EA3, the disclosure is not limited thereto. In another embodiment, for example, each of the plurality of pixels PX may include four emission areas. In an embodiment, each of the emission areas EA1, EA2, and EA3 may have a polygonal, circular, elliptical, or atypical shape in plan view, unlike those shown in FIGS. 5 and 6.

The arrangement of the emission areas EA1, EA2, and EA3 of the plurality of pixels PX is not limited to that illustrated in FIGS. 5 and 6. In an embodiment, for example, the emission areas of the plurality of pixels PX may be disposed in a stripe structure in which the emission areas are arranged in the first direction DR1, a PenTile® structure in which the emission areas are arranged in a diamond shape, or the like.

FIG. 7 is a cross-sectional view illustrating an embodiment of the display panel taken along line I-I′ of FIG. 5.

Referring to FIG. 7, an embodiment of the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. In an embodiment, for example, the first type impurity may be a p-type impurity, and the second type impurity may be an n-type impurity. Alternatively, the first type impurity may be an n-type impurity, and the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB. The first semiconductor insulating film SINS1 may include or be formed of silicon carbonitride (SiCN) or a silicon oxide (SiOx)-based inorganic film, but the disclosure is not limited thereto.

A second semiconductor insulating film SINS2 may be disposed on the first semiconductor insulating film SINS1. The second semiconductor insulating film SINS2 may include or be formed of a silicon oxide (SiOx)-based inorganic film, but the embodiment of the specification is not limited thereto.

The plurality of contact terminals CTE may be disposed on the second semiconductor insulating film SINS2. Each of the plurality of contact terminals CTE may be connected to at least one selected from the gate electrode GE, the source region SA, and the drain region DA of each of the pixel transistors PTR through contact plugs penetrating (or disposed through) the first semiconductor insulating film SINS1 and the second semiconductor insulating film INS2. The plurality of contact terminals CTE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may include or be formed of a silicon oxide (SiOx)-based inorganic film, but the embodiment of the specification is not limited thereto.

In an embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that does not bend, and the polymer resin substrate may be a flexible substrate that can be bent or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 shown in FIG. 3. In an embodiment, for example, the first to sixth transistors T1 to T6 are merely formed in the semiconductor backplane SBP, and the connection of the first to sixth transistors T1 to T6 and the first and second capacitors C1 and C2 may be implemented by the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE (see FIG. 3) may also be implemented by the first to eighth conductive layers ML1 to ML8.

The first insulating film INS1 may be disposed on the semiconductor backplane SBP. Each of the first vias VA1 may penetrate or be disposed through the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate or be disposed through the second insulating film INS2 and be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate or be disposed through the third insulating film INS3 and be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate or be disposed through the fourth insulating film INS4 and be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate or be disposed through the fifth insulating film INS5 and be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate or be disposed through the sixth insulating film INS6 and be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate or be disposed through the seventh insulating film INS7 and be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate or be disposed through the eighth insulating film INS8 and be connected to the seventh conductive layer ML7. Each of the eighth conductive layers ML8 may be disposed on the eighth insulating film INS8 and may be connected to the eighth via VA8.

The first to eighth conductive layers ML1 to ML8 may include or be made of substantially the same material. The first to eighth conductive layers ML1 to ML8 may be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The first to eighth vias VA1 to VA8 may include or be made of substantially the same material. The first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. First to eighth insulating films INS1 to INS8 may include or be formed of a silicon oxide (SiOx)-based inorganic film, but the embodiment of the specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. In an embodiment, for example, the thickness of the first conductive layer ML1 may be approximately 1360 angstrom (A). The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same as each other. In an embodiment, for example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may include or be formed of a silicon oxide (SiOx)-based inorganic film, but the embodiment of the specification is not limited thereto.

Each of the ninth vias VA9 may penetrate the ninth insulating film INS9 and be connected to the eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. In an embodiment, for example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the first reflective electrodes RL1 may include titanium nitride (TiN).

Each of the second reflective electrodes RL2 may be disposed on the first reflective electrode RL1. The second reflective electrodes RL2 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the first sub-pixel SP1. In addition, the second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to advantageously reflect the light of the second color emitted from the light-emitting stack ES. The thickness of the second step layer STPL2 may be set or determined in consideration of the wavelength of the light of the third color and a distance from the light-emitting stack ES of the third sub-pixel SP3 to the fourth reflective electrode RL4 to advantageously reflect the light of the third color emitted from the light-emitting stack ES.

The first step layer STPL1 and the second step layer STPL2 may include or be formed of silicon carbonitride (SiCN) or a silicon oxide (SiOx)-based inorganic film, but the embodiment of the specification is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the third reflective electrodes RL3 may include titanium nitride (TiN).

In another embodiment, at least one selected from the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to advantageously reflect the light. In addition, since the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. In an embodiment, for example, the fourth reflective electrodes RL4 may include aluminum (Al) or titanium (Ti).

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, among light emitted from the light-emitting elements LE. The tenth insulating film INS10 may include or be formed of a silicon oxide (SiOx)-based inorganic film, but the disclosure is not limited thereto.

Each of the tenth vias VA10 may penetrate the tenth insulating film VA10 and be connected to the reflective electrode layer RL. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof.

The thicknesses of the tenth vias VA10 may be different in the first sub-pixel SP1, the second sub-pixel SP2, and the third sub-pixel SP3 to adjust a resonance distance of light emitted from the light-emitting elements LE in at least one of the first sub-pixel SP1, the second sub-pixel SP2, or the third sub-pixel SP3. In an embodiment, for example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or a combination (e.g., an alloy) thereof. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may be provided with openings defined therein to partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or be formed of a silicon oxide (SiOx)-based inorganic film, but the embodiment of the specification is not limited thereto. The first pixel defining film PDL1, the second pixel defining film PDL2, and the third pixel defining film PDL3 may each have a thickness of about 500 Å.

In an embodiment where the first pixel defining film PDL1, the second pixel defining film PDL2, and the third pixel defining film PDL3 are formed as one pixel defining film, the height of the one pixel defining film increases, such that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to substantially reduce or effectively prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. In an embodiment, for example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. Although not shown in the drawings, the first light-emitting stack ES1 may include a hole injecting layer, a hole transporting layer, a first light-emitting layer, an electron transporting layer, and an electron injecting layer, the second light-emitting stack ES2 may include the hole injecting layer, the hole transporting layer, a second light-emitting layer, the electron transporting layer, and the electron injecting layer, and the third light-emitting stack ES3 may include the hole injecting layer, the hole transporting layer, a third light-emitting layer, the electron transporting layer, and the electron injecting layer.

In an embodiment, for example, the hole injecting layer may be disposed on the first electrodes AND exposed by the openings of the pixel defining film PDL, the inner surfaces of the openings of the pixel defining film PDL, and the top surface of the pixel defining film PDL. The hole transporting layer may be disposed on the hole injecting layer.

The first to third light-emitting layers may be respectively disposed in the openings of the pixel defining film PDL on the hole transporting layer. The first light-emitting layer may be disposed in the opening of the pixel defining film PDL in the first emission area EA1, and may emit light of a first color, for example, red light. The second light-emitting layer may be disposed in the opening of the pixel defining film PDL in the second emission area EA2, and may emit light of a second color, for example, green light. The third light-emitting layer may be disposed in the opening of the pixel defining film PDL in the third emission area EA3, and may emit light of a third color, for example, blue light.

The electron transporting layer may be disposed on the first to third light-emitting layers and the hole transporting layer, and the electron injecting layer may be disposed on the electron transporting layer.

In another embodiment, for example, although not shown, a plurality of trenches (not shown) may be disposed between the first to third emission areas EA1, EA2, and EA3. The trenches may have a ring shape respectively surrounding the first to third emission areas EA1, EA2, and EA3, and may be formed to penetrate the pixel defining film PDL. The hole injecting layer and the hole transporting layer formed on the first electrodes AND of the first to third emission areas EA1, EA2, and EA3 may be disconnected from each other by the trenches.

In another embodiment, for example, the first to third light-emitting stacks ES1, ES2, and ES3 may be respectively disposed in the openings of the pixel defining film PDL, and may not be disposed on the pixel defining film PDL. In such an embodiment, the first to third light-emitting stacks ES1, ES2, and ES3 may be disconnected from each other by the pixel defining film PDL.

The second electrode CAT may be disposed on the first to third light-emitting stacks ES1, ES2, and ES3. The second electrode CAT may include or be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT includes or is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to substantially reduce or effectively prevent oxygen or moisture from permeating into the display element layer EML. display element layer example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer (or have a multilayer structure) in which one or more inorganic films selected from silicon nitride (SiNx), silicon oxynitride (SiON), and silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may include or be formed of titanium oxide (TiOx) or aluminum oxide (AlOx), but the embodiment of the specification is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as acrylic resin, epoxy resin, phenolic resin, polyamide resin, or polyimide resin.

The cover layer CVL may be disposed on the adhesive layer APL. The cover layer CVL may be a glass substrate or a polymer resin. In an embodiment where the cover layer CVL is a glass substrate, the cover layer CVL may be attached onto the adhesive layer APL, and may serve as an encapsulation substrate. In an embodiment where the cover layer CVL is a polymer resin, the cover layer CVL may be directly applied onto the adhesive layer APL.

The polarizing plate POL may be disposed on the cover layer CVL. The polarizing plate POL may be a structure for substantially reducing or effectively preventing visibility degradation caused by reflection of external light. The polarizing plate POL may include a linear polarizing plate and a phase retardation film. In an embodiment, for example, the phase retardation film may be a λ/4 plate (quarter-wave plate), but the disclosure is not limited thereto.

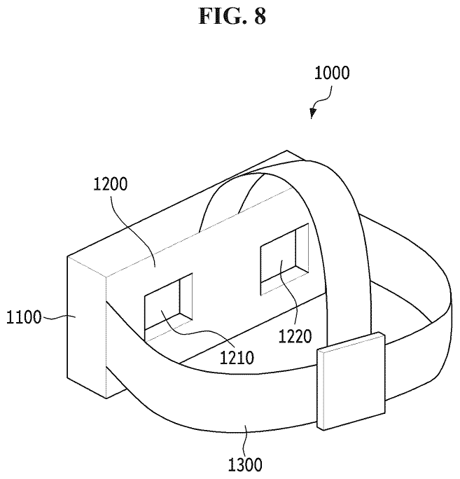

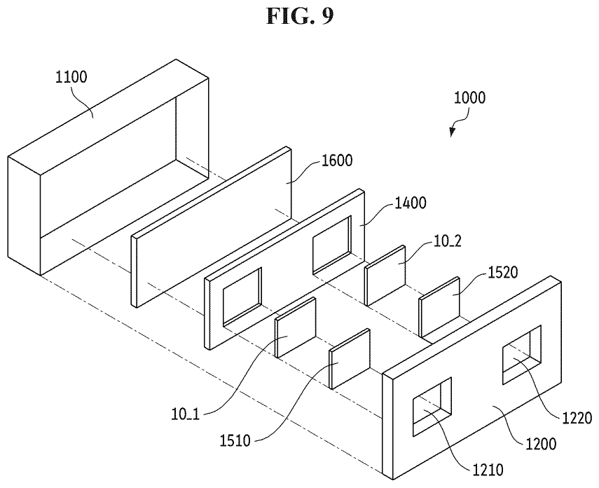

FIG. 8 is a schematic perspective view illustrating an embodiment of a head mounted display. FIG. 9 is a schematic exploded perspective view illustrating an embodiment of the head mounted display shown in FIG. 8.

Referring to FIGS. 8 and 9, a head mounted display 1000 according to an embodiment may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Since each of the first display device 10_1 and the second display device 10_2 is substantially the same as the display device 10 described in conjunction with FIGS. 1 and 2, any repetitive detailed description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

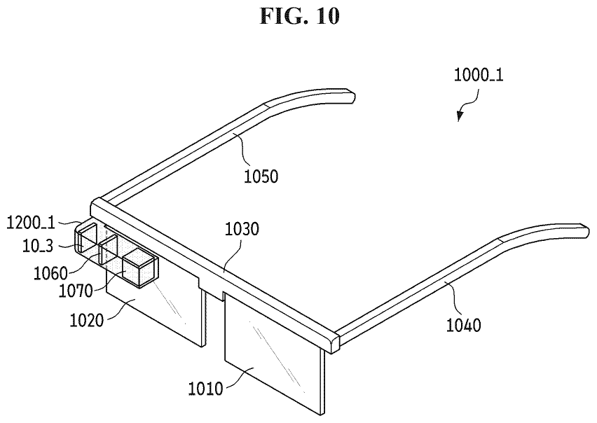

The head mounted band 1300 serves to secure the display device housing 1100 to the user's head such that the first eyepiece 1210 and the second eyepiece 1220 of the housing cover 1200 remain located on the user's left and right eyes, respectively. In an embodiment where the display device housing 1100 is desired to be lightweight and compact, the head mounted display 1000 may be provided in the form of glasses as shown in FIG. 10.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another embodiment of a head mounted display.

Referring to FIG. 10, an embodiment of a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 10_3, the optical member 1060, and the optical path conversion member 1070. The image displayed on the display device 10_3 may be magnified by the optical member 1060, and may be provided to the user's right eye through the right eye lens 1020 after the optical path thereof is changed by the optical path conversion member 1070. As a result, the user may view an augmented reality image, through the right eye, in which a virtual image displayed on the display device 10_3 and a real image seen through the right eye lens 1020 are combined.

FIG. 10 illustrates an embodiment where the display device housing 1200_1 is disposed at the right end of the support frame 1030, but the disclosure is not limited thereto. In another embodiment, for example, the display device housing 1200_1 may be disposed at the left end of the support frame 1030, and in such an embodiment, the image of the display device 10_3 may be provided to the user's left eye. In another embodiment, for example, the display device housing 1200_1 may be disposed at both the left and right ends of the support frame 1030, and in such an embodiment, the user may view the image displayed on the display device 10_3 through both the left and right eyes.

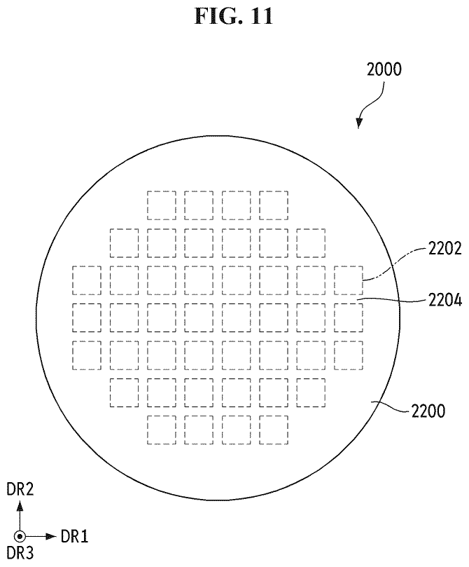

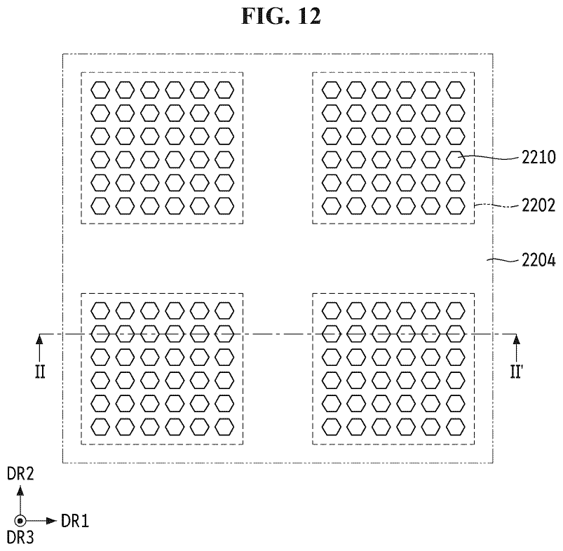

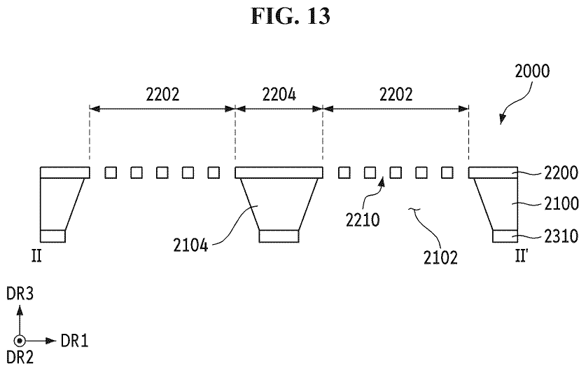

FIG. 11 is a schematic plan view illustrating a deposition mask according to an embodiment of the disclosure. FIG. 12 is a schematic plan view illustrating cell regions and a grid region shown in FIG. 11. FIG. 13 is a schematic cross-sectional view taken along line II-II′ shown in FIG. 12.

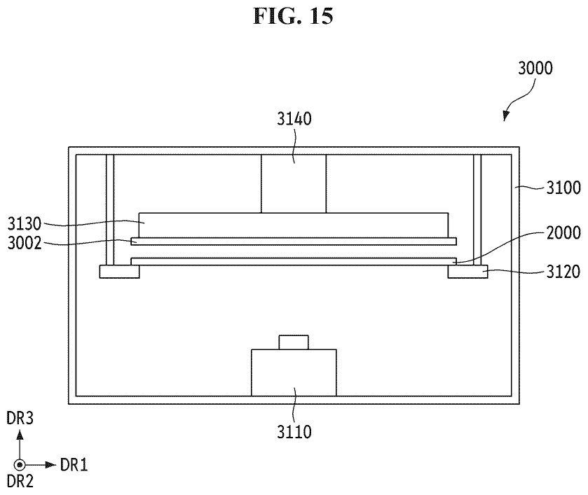

Referring to FIGS. 11 to 13, a deposition mask 2000 according to an embodiment of the disclosure may be used as a shadow mask in a deposition process for forming light emitting layers of a light emitting stack ES on a backplane substrate 3002 (refer to FIG. 15). In an embodiment of the disclosure, a deposition mask 2000 may be used to form light-emitting layers of the light-emitting stack ES on the backplane substrate 3002 in a manufacturing process of the display panel 100 (see FIG. 1). For example, as illustrated in FIG. 7, the semiconductor backplane SBP and the light emitting element backplane EBP may be disposed on the backplane substrate 3002, and the reflective electrodes RL and the insulating film INS10 may be disposed on the light emitting element backplane EBP. Electrode patterns, for example, the first electrodes AND may be disposed on the insulating film INS10, and the first electrodes AND may be electrically connected to the reflective electrodes RL through the vias VA10. For example, the deposition mask 2000 may be used to form light-emitting layers on the electrode patterns. As an example, the deposition mask 2000 may be used to form first light-emitting layers for emitting first light having a red wavelength band on the first electrodes AND of the first emission areas EA1. As another example, the deposition mask 2000 may be used to form second light-emitting layers for emitting second light having a green wavelength band on the first electrodes AND of the second emission areas EA2. As still another example, the deposition mask 2000 may be used to form third light-emitting layers for emitting third light having a blue wavelength band on the first electrodes AND of the third emission areas EA3. In an embodiment of the disclosure, the deposition mask 2000 may include a mask frame 2100 and a membrane 2200 disposed on the mask frame 2100.

The membrane 2200 may include at least one cell region 2202. In an embodiment, for example, as shown in FIG. 11, the membrane 2200 may include a plurality of cell regions 2202 arranged in a matrix form along a first direction DR1 and a second direction DR2 crossing the first direction DR1 and a grid region 2204 disposed between the cell regions 2202. For example, the second direction DR2 may be a direction perpendicular to the first direction DR1. Herein, the third direction DR3 may be a direction perpendicular to the first direction DR1 and the second direction DR2 or a thickness direction of the membrane 2200. However, the number of cell regions 2202 and arrangement directions of the cell regions 2202 may be variously changed, and thus, the scope of the disclosure is not limited by the number of cell regions 2202 and the arrangement directions of the cell regions 2202.

In an embodiment, the mask frame 2100 may be provided with a plurality of cell openings 2102 exposing the cell regions 2202 of the membrane 2200, and may include a rib region 2104 defining the cell openings 2102. In such an embodiment, the cell regions 2202 of the membrane 2200 may be disposed on the cell openings 2102 of the mask frame 2100, respectively, and the grid region 2204 of the membrane 2200 may be disposed on the rib region 2104 of the mask frame 2100.

Each of the cell regions 2202 of the membrane 2200 may be provided with a plurality of pixel openings 2210. The plurality of pixel openings 2210 may be formed or defined completely through each of the cell regions 2202. That is, the pixel openings 2210 of the membrane 2200 may be in communication with the cell openings 2102 of the mask frame 2100, and the cell openings 2102 of the mask frame 2100 and the pixel openings 2210 of the membrane 2200 may function as paths for providing light emitting materials onto anode electrodes of a backplane substrate 3002 (see FIG. 15) in the deposition process for forming the light emitting layers. In an embodiment, for example, as shown in FIG. 12, the pixel openings 2210 may be arranged in a matrix form along the first direction DR1 and the second direction DR2.

A rear inorganic film pattern 2310 may be disposed on a rear surface of the mask frame 2100 opposing a front surface of the mask frame 2100 on which the membrane 2200 is disposed. The rear inorganic film pattern 2310 may be used as an etching mask in an etching process for forming cell openings 2102. In addition, the rear inorganic film pattern 2310 may include or be made of a same material as the membrane 2200, and may be formed simultaneously with the membrane 2200 by a same process.

According to an embodiment of the disclosure, the mask frame 2100 may include silicon, and the membrane 2200 may include silicon nitride. In an embodiment, for example, a semiconductor substrate such as a silicon wafer may be used as the mask frame 2100, and a silicon nitride film formed on the silicon wafer may be used as the membrane 2200. In an embodiment, the membrane 2200 may be formed on the mask frame 2100 through a thermal chemical vapor deposition (TCVD) process. In such an embodiment, interfacial residual stress may occur between the mask frame 2100 and the membrane 2200 due to an atomic arrangement, a molecular structure, and the like, of the membrane 2200, and warpage may occur in the deposition mask 2000 due to the interfacial residual stress. In an embodiment, for example, smile warpage or crying warpage may occur in the deposition mask 2000 depending on a magnitude of the interfacial residual stress, and twist warpage may occur in the deposition mask 2000 depending on a distribution of the interfacial residual stress.

The interfacial residual stress between the mask frame 2100 and the membrane 2200 may be adjusted by process conditions of the TCVD process, and it is desired to make the interfacial residual stress as small as possible to improve the warpage of the deposition mask 2000. According to an embodiment of the disclosure, the interfacial residual stress between the mask frame 2100 and the membrane 2200 is adjusted to be in a range of about −30 megapascals (MPa) to about 30 MPa to reduce the warpage of the deposition mask 2000. In an embodiment, for example, the interfacial residual stress between the mask frame 2100 and the membrane 2200 may be adjusted by controlling a temperature, a pressure, or a flow rate ratio between source gases in the TCVD process.

According to an embodiment of the disclosure, the membrane 2200 may be a silicon-rich silicon nitride film. The silicon-rich silicon nitride film may have an atomic arrangement similar to that of the silicon wafer used as the mask frame 2100, and accordingly, the interfacial residual stress between the mask frame 2100 and the membrane 2200 may be reduced. In an embodiment, for example, the membrane 2200 may have a silicon content higher than a silicon content of stoichiometric silicon nitride (Si₃N₄). In this case, the stoichiometric silicon nitride refers to a silicon nitrogen compound having a thermodynamically stable quantitative relationship. Accordingly, when silicon nitride is expressed as SiₓN_{y}, silicon-rich silicon nitride refers to a case where ‘x/y’ has a value greater than 0.75. In an embodiment, for example, the membrane 2200 may include or be made of silicon-rich silicon nitride having an ‘x/y’ value of about 0.8 or greater and about 3.0 or less.

The silicon-rich silicon nitride film may be formed through a TCVD process. The TCVD process may be performed at a low pressure and a high temperature, for example, under a pressure (pressure atmosphere or pressure condition) in a range of about 210 millitorr (mTorr) to about 250 mTorr and a temperature (temperature atmosphere or temperature condition) in a range of about 800° C. to about 850° C. The silicon-rich silicon nitride film may be formed by a reaction between a first source gas including silicon and a second source gas including nitrogen. In an embodiment, for example, a dichlorosilane (DCS) (SiH₂Cl₂) gas may be used as the first source gas, and an ammonia (NH₃) gas may be used as the second source gas.

In particular, to form the silicon-rich silicon nitride film having a relatively higher silicon content than the stoichiometric silicon nitride, a supply flow rate ratio between the first source gas and the second source gas may be appropriately adjusted in a range of about 10:1 to about 10:1.7. In an embodiment, for example, the supply flow rate ratio between the first source gas and the second source gas may be kept constant during a period in which the TCVD process is performed, and accordingly, a nitrogen content of the membrane 2200 may be kept constant in a thickness direction of the membrane 2200, that is, the third direction DR3.

In another embodiment, for example, the supply flow rate ratio between the first source gas and the second source gas may gradually or continuously increase from about 10:1 to about 10:1.7 during the period in which the TCVD process is performed, and accordingly, a nitrogen content of the membrane 2200 may gradually or continuously increase from an interface between the mask frame 2100 and the membrane 2200 in the thickness direction of the membrane 2200, that is, the third direction DR3. In an embodiment, the silicon content of the membrane 2200 may gradually or continuously decrease from the interface between the mask frame 2100 and the membrane 2200 in the thickness direction of the membrane 2200, that is, the third direction DR3. In such an embodiment, the silicon content of the membrane 2200 may be highest near the interface between the mask frame 2100 and the membrane 2200, and accordingly, the interfacial residual stress between the mask frame 2100 and the membrane 2200 may be substantially reduced or effectively prevented.

According to an embodiment of the disclosure as described above, the membrane 2200 including or made of the silicon-rich silicon nitride may have the atomic arrangement similar to that of the silicon wafer used as the mask frame 2100, and accordingly, the interfacial residual stress between the mask frame 2100 and the membrane 2200 may be controlled to be in a range of about −30 MPa to about 30 MPa. As a result, the warpage of the deposition mask 2000 may be substantially reduced or effectively prevented.

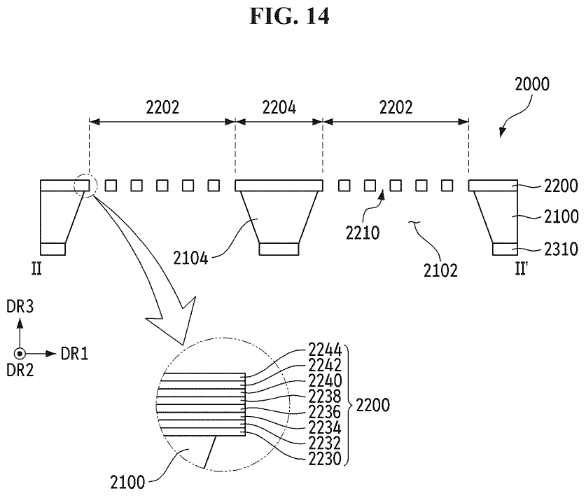

FIG. 14 is a schematic cross-sectional view illustrating a deposition mask according to another embodiment of the disclosure.

Referring to FIG. 14, an embodiment of a deposition mask 2000 may include a mask frame 2100 having a cell opening 2102 and a membrane 2200 disposed on the mask frame 2100. In an embodiment, for example, the mask frame 2100 may have a plurality of cell openings 2102, and may include a rib region 2104 defining the plurality of cell openings 2102. The membrane 2200 may include cell regions 2202 respectively disposed on the cell openings 2102 of the mask frame 2100 and a grid region 2204 disposed on the rib region 2104 of the mask frame 2100. In such an embodiment, configurations other than a configuration of the membrane 2200 are substantially the same as those described above with reference to FIGS. 11 to 13, and any repetitive detailed description thereof will hereinafter be omitted.

According to an embodiment, the membrane 2200 may include a plurality of silicon nitride films 2230 to 2244 stacked on the mask frame 2100. In an embodiment, For example, the membrane 2200 may include silicon-rich silicon nitride films 2230 to 2244 formed on the mask frame 2100 through a TCVD process. The TCVD process may be performed at a low pressure and a high temperature, for example, under a pressure in a range of about 210 mTorr to about 250 mTorr and a temperature in a range of about 800° C. to about 850° C. The silicon-rich silicon nitride films 2230 to 2244 may be formed by a reaction between a first source gas including silicon and a second source gas including nitrogen.

In an embodiment, for example, a DCS (SiH₂Cl₂) gas may be used as the first source gas, and an ammonia (NH₃) gas may be used as the second source gas. In such an embodiment, the silicon-rich silicon nitride films 2230 to 2244 may have a silicon content higher than a silicon content of stoichiometric silicon nitride, and may be formed by stepwise changing a supply flow rate ratio between the first source gas and the second source gas from about 10:1 to about 10:1.7 during a period in which the TCVD process is performed.

In an embodiment, for example, the supply flow rate ratio between the first source gas and the second source during the formation of a first silicon nitride film 2230 may be controlled to be about 10:1, the supply flow rate ratio between the first source gas and the second source during the formation of a second silicon nitride film 2232 may be controlled to be about 10:1.1, the supply flow rate ratio between the first source gas and the second source during the formation of a third silicon nitride film 2234 may be controlled to be about 10:1.2, the supply flow rate ratio between the first source gas and the second source during the formation of a fourth silicon nitride film 2236 may be controlled to be about 10:1.3, the supply flow rate ratio between the first source gas and the second source during the formation of a fifth silicon nitride film 2238 may be controlled to be about 10:1.4, the supply flow rate ratio between the first source gas and the second source during the formation of a sixth silicon nitride film 2240 may be controlled to be about 10:1.5, the supply flow rate ratio between the first source gas and the second source during the formation of a seventh silicon nitride film 2242 may be controlled to be about 10:1. 6, and the supply flow rate ratio between the first source gas and the second source during the formation of an eighth silicon nitride film 2244 may be controlled to be about 10:1.7.

During the formation of the silicon nitride films 2230 to 2244, a deposition rate may be controlled to be about 1.2 nanometers per minute (nm/min). In an embodiment, for example, a thickness of each of the silicon nitride films 2230 to 2244 may be controlled to be about 125 nm to 150 nm, and as illustrated in FIG. 14, the membrane 2200 may include eight silicon nitride films 2230 to 2244. That is, the membrane 2200 may be formed to have a thickness in a range of about 1 micrometer (μm) to about 1.2 μm. However, the number of silicon nitride films 2230 to 2244, the thickness of each of the silicon nitride films 2230 to 2244, and the thickness of the membrane 2200 may be changed or modified, and accordingly, the scope of the disclosure is not limited by the number of silicon nitride films 2230 to 2244, the thickness of each of the silicon nitride films 2230 to 2244, and the thickness of the membrane 2200 described above.

According to an embodiment, by stepwise controlling the supply flow rate ratio between the first source gas and the second source gas, a nitrogen content of the silicon nitride films 2230 to 2244 may stepwise increase from an interface between the mask frame 2100 and the membrane 2200 in a direction in which the silicon nitride films 2230 to 2244 are stacked. In such an embodiment, by stepwise controlling the supply flow rate ratio between the first source gas and the second source gas, a silicon content of the silicon nitride films 2230 to 2244 may stepwise decrease from the interface between the mask frame 2100 and the membrane 2200 in the direction in which the silicon nitride films 2230 to 2244 are stacked. In an embodiment, for example, the first silicon nitride film 2230 may have the highest silicon content among the silicon nitride films 2230 to 2244, and the eighth silicon nitride film 2244 may have the lowest silicon content among the silicon nitride films 2230 to 2244.

The uppermost silicon nitride film of the silicon nitride films 2230 to 2244, that is, the silicon nitride film having the lowest silicon content among the silicon nitride films 2230 to 2244, for example, the eighth silicon nitride film 2244, may have a silicon content higher than the silicon content of the stoichiometric silicon nitride. That is, when the eighth silicon nitride film 2244 is expressed as SiₓN_{y}, an ‘x/y’ value of the eighth silicon nitride film 2244 may be greater than 0.75. In addition, when each of the silicon nitride films 2230 to 2244 is expressed as SiₓN_{y}, an ‘x/y’ average value of the silicon nitride films 2230 to 2244 may be greater than 0.75. In an embodiment, for example, the ‘x/y’ average value of the silicon nitride films 2230 to 2244 may be about 0.8 or greater and about 3.0 or less.

According to an embodiment, a nitrogen content of the first silicon nitride film 2230 may be relatively lower than those of the other silicon nitride films 2232 to 2244, and a silicon content of the first silicon nitride film 2230 may be relatively higher than those of the other silicon nitride films 2232 to 2244. As a result, an atomic arrangement of the first silicon nitride film 2230 may be similar to the atomic arrangement of the silicon wafer used as the mask frame 2100, and accordingly, interfacial residual stress between the first silicon nitride film 2230 and the mask frame 2100 may be significantly reduced. As a result, the warpage of the deposition mask 2000 may be substantially reduced or effectively prevented.

FIG. 15 is a schematic view illustrating an embodiment of a deposition apparatus including the deposition mask shown in FIGS. 11 to 13 or FIG. 14.

Referring to FIG. 15, an embodiment of a deposition apparatus 3000 may be used to form light emitting layers on a backplane substrate 3002. In such an embodiment, electrode patterns such as anode electrodes AND may be disposed on the backplane substrate 3002, and the deposition apparatus 3000 may be used to form red light emitting layers, green light emitting layers, and blue light emitting layers on the electrode patterns.

In an embodiment, for example, the deposition apparatus 3000 may include a process chamber 3100, a deposition source 3110 disposed in the process chamber 3100, a deposition mask 2000 disposed above the deposition source 3110, a support member 3120 that supports the deposition mask 2000, an electrostatic chuck 3130 which is disposed above the deposition mask 2000 and supports the backplane substrate 3002, and the like.

The process chamber 3100 may define an internal space that is sealed, and a deposition process for forming the light emitting layers on the backplane substrate 3002 may be performed in the internal space of the process chamber 3100. The process chamber 3100 may be connected to a vacuum pump (not illustrated), and a vacuum atmosphere or condition may be created in the internal space of the process chamber 3100 by the vacuum pump.

The deposition source 3110 may be disposed inside the process chamber 3100, and a deposition material may be accommodated inside the deposition source 3110. The deposition source 3110 may evaporate a deposition material such as an organic material, an inorganic material, or a conductive material toward the backplane substrate 3002, and the evaporated deposition material may be deposited on the backplane substrate 3002 through the deposition mask 2000. In an embodiment, for example, the deposition source 3110 may evaporate an organic material for forming the light emitting layers on the backplane substrate 3002, and may include a heater (not shown) for evaporating the organic material.

The support member 3120 for supporting the deposition mask 2000 may be disposed above the deposition source 3110. In an embodiment, for example, the support member 3120 may support an edge portion of the deposition mask 2000. Although not shown, the support member 3120 may be configured to be movable in a vertical or horizontal direction and rotatable by a separate driver (not shown) to adjust or control a position and an angle of the deposition mask 2000.

The electrostatic chuck 3130 for supporting the backplane substrate 3002 may be disposed above the deposition mask 2000. The electrostatic chuck 3130 may hold the backplane substrate 3002 using electrostatic force in a way such that the backplane substrate 3002 faces downward, that is, the backplane substrate 3002 faces the deposition mask 2000. In such an embodiment, the backplane substrate 3002 may be disposed in a way such that the anode electrodes face the deposition mask 2000.

The electrostatic chuck 3130 may be configured to be movable in the vertical or horizontal direction and rotatable by a chuck driver 3140 to adjust or control a position and an angle of the backplane substrate 3002. In addition, after the deposition mask 2000 is disposed on the support member 3120 and the backplane substrate 3002 is held at a lower portion of the electrostatic chuck 3130, positional alignment between the backplane substrate 3002 and the deposition mask 2000 may be performed. In an embodiment, for example, after the backplane substrate 3002 and the deposition mask 2000 are aligned with each other so that the pixel openings 2210 of the deposition mask 2000 face the anode electrodes AND of at least one selected from the light emitting stacks ES1, ES2, and ES3, the electrostatic chuck 3130 may be lowered by the chuck driver 3140 or the support member 3120 may be raised by the separate driver, and accordingly, the deposition mask 2000 and the backplane substrate 3002 may be in close contact with each other. In such an embodiment, the membrane 2200 of the deposition mask 2000 may be in close contact with the backplane substrate 3002, and accordingly, the pixel openings 2210 defined or formed through the membrane 2200 may be disposed adjacent to the electrode patterns of the backplane substrate.

After the backplane substrate 3002 is in close contact with the deposition mask 2000 as described above, the deposition source 3110 may evaporate an organic material, and the evaporated organic material may be deposited on the electrode patterns of the backplane substrate 3002 through the cell openings 2102 and the pixel openings 2210 of the deposition mask 2000. In such an embodiment, the interfacial residual stress between the mask frame 2100 and the membrane 2200 is in a range of about −30 MPa to about 30 MPa, which is very small, and thus, the warpage of the deposition mask 2000 may be substantially reduced or effectively prevented. Accordingly, a gap between the deposition mask 2000 and the backplane substrate 3002 may be kept constant, and parallelism between the deposition mask 2000 and the backplane substrate 3002 may be improved. As a result, pixel position accuracy (PPA) of deposition material layers formed on the backplane substrate 3002 by the deposition process may be improved, and a color mixing defect between adjacent sub-pixels SP1, SP2, and SP3 may be sufficiently reduced or effectively prevented.

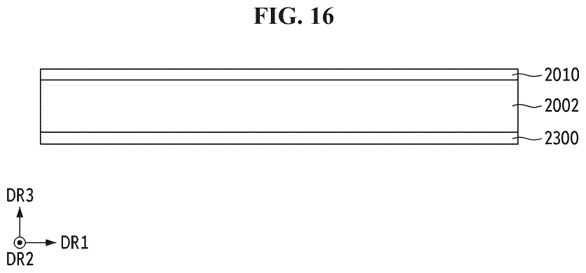

FIGS. 16 to 21 are schematic cross-sectional views illustrating a method of manufacturing a deposition mask according to an embodiment of the disclosure.

Referring to FIG. 16, in an embodiment of a method of manufacturing a deposition mask, an inorganic film 2010 may be formed on a substrate 2002. In an embodiment, for example, a semiconductor substrate such as a silicon wafer may be used as the substrate 2002, and may function as the mask frame 2100 of the deposition mask 2000. The inorganic film 2010 may be formed at a thickness in a range of about 1 μm to about 1.2 μm on the silicon wafer through a TCVD process, and may function as the membrane 2200 of the deposition mask 2000.

The inorganic film 2010 may include silicon nitride, and a first source gas including silicon and a second source gas including nitrogen may be supplied into a process chamber of a deposition apparatus for performing the TCVD process. In an embodiment, for example, a DCS gas may be used as the first source gas, an ammonia (NH₃) gas may be used as the second source gas, and the inorganic film 2010 may be formed by a reaction between the first source gas and the second source gas.

According to an embodiment, the inorganic film 2010 may include or be made of silicon-rich silicon nitride to reduce interfacial residual stress between the substrate 2002 and the inorganic film 2010. That is, the inorganic film 2010 may be a silicon-rich silicon nitride film formed on the substrate 2002. The silicon-rich silicon nitride film may have a silicon content higher than a silicon content of stoichiometric silicon nitride (Si₃N₄). Accordingly, the silicon-rich silicon nitride film may have an atomic arrangement similar to that of the silicon wafer used as the substrate 2002, and accordingly, the interfacial residual stress between the substrate 2002 and the inorganic film 2010 may be reduced. In an embodiment, when silicon nitride is expressed as SiₓN_{y}, the silicon-rich silicon nitride refers to a case where ‘x/y’ has a value greater than 0.75. In an embodiment, for example, the inorganic film 2010 may include or be made of silicon-rich silicon nitride having an ‘x/y’ value of about 0.8 or more and about 3.0 or less.

A silicon content and a nitrogen content of the inorganic film 2010 may be adjusted by controlling process conditions during a period in which the TCVD process is performed, and the interfacial residual stress between the substrate 2002 and the inorganic film 2010 may be changed depending on the silicon content and the nitrogen content of the inorganic film 2010. That is, the interfacial residual stress between the substrate 2002 and the inorganic film 2010 may be controlled by controlling the process conditions during the period in which the TCVD process is performed. In an embodiment, for example, to effectively reduce warpage of the deposition mask 2000, the process conditions may be controlled in a way such that the interfacial residual stress between the substrate 2002 and the inorganic film 2010 is in a range of about −30 MPa to about 30 MPa.

According to the embodiment, the TCVD process may be performed at a low pressure and a high temperature to form the silicon-rich silicon nitride film on the substrate 2002, and a supply flow rate ratio of the second source gas to the first source gas may be less than about 0.2. In an embodiment, for example, the TCVD process may be performed under a pressure in a range of about 210 mTorr to about 250 mTorr and a temperature in a range of about 800° C. to about 850° C., and a supply flow rate ratio between the first source gas and the second source gas may be appropriately controlled in a range of about 10:1 to about 10:1.7. In an embodiment, for example, the supply flow rate ratio between the first source gas and the second source gas may be kept constant during the period in which the TCVD process is performed, and accordingly, the nitrogen content of the inorganic film 2010 may be kept constant in a thickness direction of the inorganic film 2010, that is, the third direction DR3.

In another embodiment, for example, the supply flow rate ratio between the first source gas and the second source gas may gradually or continuously increase from about 10:1 to about 10:1.7 during the period in which the TCVD process is performed, and accordingly, the nitrogen content of the inorganic film 2010 may gradually or continuously increase from an interface between the substrate 2002 and the inorganic film 2010 in the thickness direction of the inorganic film 2010, that is, the third direction DR3. In an embodiment, the silicon content of the inorganic film 2010 may gradually or continuously decrease from the interface between the substrate 2002 and the inorganic film 2010 in the thickness direction of the inorganic film 2010, that is, the third direction DR3. In such an embodiment, the silicon content of the inorganic film 2010 may be highest near the interface between the substrate 2002 and the inorganic film 2010, and accordingly, the interfacial residual stress between the substrate 2002 and the inorganic film 2010 may be significantly reduced.

In an embodiment, the inorganic film 2010 may be formed on a front surface of the substrate 2002, and a rear inorganic film 2300 may be formed on a rear surface of the substrate 2002. In an embodiment, for example, the inorganic film 2010 and the rear inorganic film 2300 may be formed simultaneously through the TCVD process, and accordingly, the inorganic film 2010 and the rear inorganic film 2300 may include or be made of the same material. In such an embodiment, the rear inorganic film 2300 may be a silicon-rich silicon nitride film, and may have a same silicon content and nitrogen content as the inorganic film 2010.

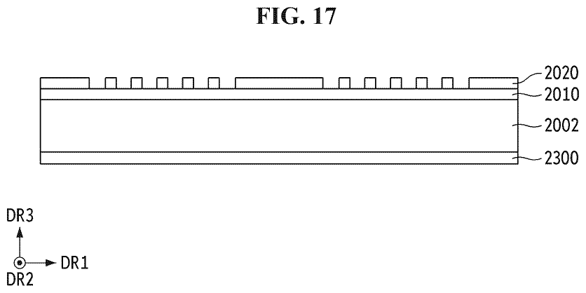

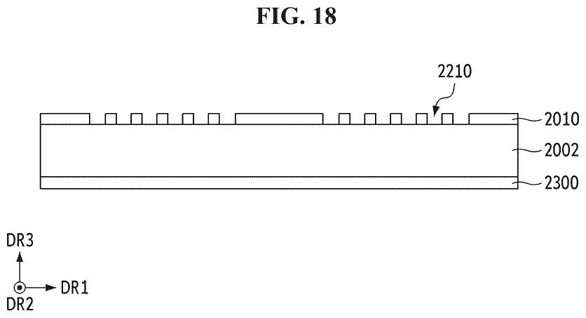

Referring to FIGS. 17 and 18, pixel openings 2210 exposing the substrate 2002 may be formed by patterning the inorganic film 2010. In an embodiment, for example, after a first photoresist pattern 2020 exposing portions where the pixel openings 2210 are to be formed is formed on the inorganic film 2010 as shown in FIG. 17, the pixel openings 2210 may be formed as shown in FIG. 18 by performing an etching process using the first photoresist pattern 2020 as an etching mask. In an embodiment, for example, the pixel openings 2210 may be formed through a reactive ion etching (RIE) process using a reaction gas such as CHF₃, CH₃F, CH₂F₂, CHF₆, CF₄, C₂F₆, or C₃F₆, and a sputtering gas such as Ar or O₂/Ar. In such an embodiment, an inductively coupled plasma (ICP) source or a capacitively coupled plasma (CCP) source may be used as a plasma source. In such an embodiment, by appropriately controlling flow rates of the reaction gas and the sputtering gas, an internal temperature of the process chamber, radio frequency (RF) power for plasma formation, bias power applied to a chuck on which the substrate is placed, and the like, the pixel openings 2210 may be formed to have a constant width in the thickness direction of the inorganic film 2010. In an embodiment, the first photoresist pattern 2020 may be removed through a stripping and/or ashing process after the pixel openings 2210 are formed.

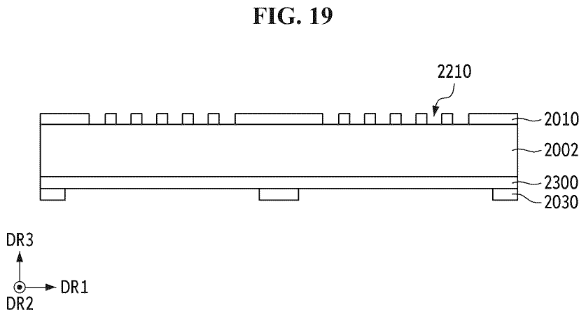

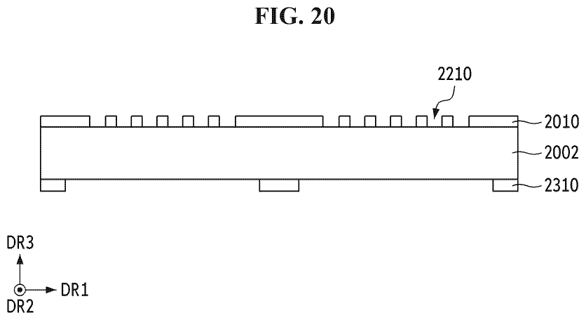

Referring to FIGS. 19 to 21, cell openings 2102 that are connected to (or in communication with) the pixel openings 2210 may be formed by patterning the substrate 2002. In an embodiment, for example, after a second photoresist pattern 2030 exposing portions where the cell openings 2102 are to be formed is formed on the rear inorganic film 2300 as shown in FIG. 19, a rear inorganic film pattern 2310 may be formed on the rear surface of the substrate 2002, as shown in FIG. 20, by performing an anisotropic etching process such as an RIE process using the second photoresist pattern 2030 as an etching mask. The second photoresist pattern 2030 may be removed through a stripping and/or ashing process after the rear inorganic film pattern 2310 is formed.

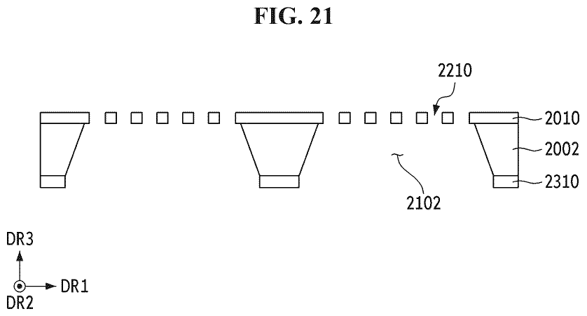

Subsequently, as shown in FIG. 21, the substrate 2002 may be partially removed in a way such that the pixel openings 2210 are exposed through a wet etching process using the rear inorganic film pattern 2310 as an etching mask, and accordingly, the cell openings 2102 that are connected to or in communication with the pixel openings 2210 may be formed. In an embodiment, for example, the wet etching process may be performed using an etchant including tetramethyl ammonium hydroxide (TMAH) or potassium hydroxide (KOH).

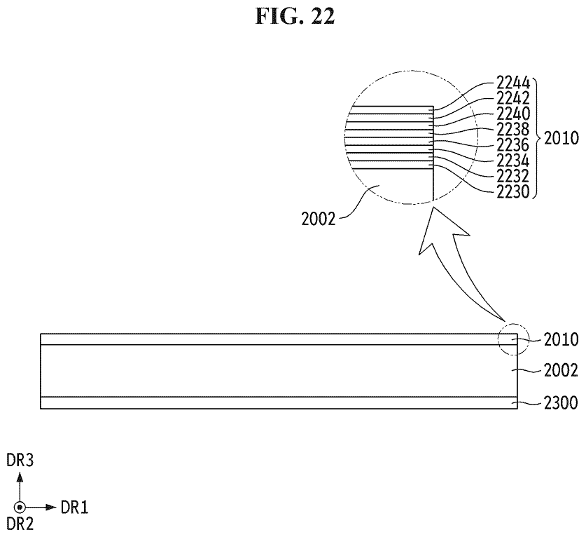

FIG. 22 is a schematic cross-sectional view illustrating a method of manufacturing a deposition mask according to another embodiment of the disclosure.

Referring to FIG. 22, in an embodiment of a method of manufacturing a deposition mask, an inorganic film 2010 may be formed on a substrate 2002. In an embodiment, for example, a semiconductor substrate such as a silicon wafer may be used as the substrate 2002, and may function as the mask frame 2100 of the deposition mask 2000. The inorganic film 2010 may include silicon nitride, and may function as the membrane 2200 of the deposition mask 2000.

According to an embodiment, the inorganic film 2010 may include a plurality of silicon nitride films 2230 to 2244 stacked on the substrate 2002. In an embodiment, for example, the inorganic film 2010 may include a plurality of silicon-rich silicon nitride films 2230 to 2244 formed on the substrate 2002, and the silicon-rich silicon nitride films 2230 to 2244 may be formed through a TCVD process. The TCVD process may be performed at a low pressure and a high temperature, for example, under a pressure in a range of about 210 mTorr to about 250 mTorr and a temperature in a range of about 800° C. to about 850° C. The silicon-rich silicon nitride films 2230 to 2244 may be formed by a reaction between a first source gas including silicon and a second source gas including nitrogen.

In an embodiment, for example, a DCS gas may be used as the first source gas, and an ammonia (NH₃) gas may be used as the second source gas. In such an embodiment, each of the silicon-rich silicon nitride films 2230 to 2244 may be formed to have a silicon content higher than a silicon content of stoichiometric silicon nitride. In an embodiment, for example, the silicon-rich silicon nitride films 2230 to 2244 may be formed by stepwise changing a supply flow rate ratio between the first source gas and the second source gas from about 10:1 to about 10:1.7 during a period in which the TCVD process is performed.

In an embodiment, for example, the supply flow rate ratio between the first source gas and the second source during the formation of the first silicon nitride film 2230 may be controlled to be about 10:1, the supply flow rate ratio between the first source gas and the second source during the formation of the second silicon nitride film 2232 may be controlled to be about 10:1.1, the supply flow rate ratio between the first source gas and the second source during the formation of the third silicon nitride film 2234 may be controlled to be about 10:1.2, the supply flow rate ratio between the first source gas and the second source during the formation of the fourth silicon nitride film 2236 may be controlled to be about 10:1.3, the supply flow rate ratio between the first source gas and the second source during the formation of the fifth silicon nitride film 2238 may be controlled to be about 10:1.4, the supply flow rate ratio between the first source gas and the second source during the formation of the sixth silicon nitride film 2240 may be controlled to be about 10:1.5, the supply flow rate ratio between the first source gas and the second source during the formation of the seventh silicon nitride film 2242 may be controlled to be about 10:1. 6, and the supply flow rate ratio between the first source gas and the second source during the formation of the eighth silicon nitride film 2244 may be controlled to be about 10:1.7.

During the formation of the silicon nitride films 2230 to 2244, a deposition rate may be controlled to be about 1.2 nm/min. In an embodiment, for example, a thickness of each of the silicon nitride films 2230 to 2244 may be controlled to be in a range about 125 nm to 150 nm, and as shown in FIG. 22, the inorganic film 2010 may include eight silicon nitride films 2230 to 2244. That is, the inorganic film 2010 may be formed to have a thickness in a range of about 1 μm to about 1.2 μm. However, the number of silicon nitride films 2230 to 2244, the thickness of each of the silicon nitride films 2230 to 2244, and the thickness of the inorganic film 2010 may be changed, and accordingly, the scope of the disclosure is not limited by the number of silicon nitride films 2230 to 2244, the thickness of each of the silicon nitride films 2230 to 2244, and the thickness of the inorganic film 2010.

According to an embodiment, by stepwise controlling the supply flow rate ratio between the first source gas and the second source gas, a nitrogen content of the silicon nitride films 2230 to 2244 may stepwise increase from an interface between the substrate 2002 and the inorganic film 2010 in a direction in which the silicon nitride films 2230 to 2244 are stacked. In such an embodiment, by stepwise controlling the supply flow rate ratio between the first source gas and the second source gas, a silicon content of the silicon nitride films 2230 to 2244 may stepwise decrease from the interface between the substrate 2002 and the inorganic film 2010 in the direction in which the silicon nitride films 2230 to 2244 are stacked. In an embodiment, for example, the first silicon nitride film 2230 may have the highest silicon content among the silicon nitride films 2230 to 2244, and the eighth silicon nitride film 2244 may have the lowest silicon content among the silicon nitride films 2230 to 2244.

The uppermost silicon nitride film of the silicon nitride films 2230 to 2244, that is, the silicon nitride film having the lowest silicon content among the silicon nitride films 2230 to 2244, for example, the eighth silicon nitride film 2244, may have a silicon content higher than the silicon content of the stoichiometric silicon nitride. That is, when the eighth silicon nitride film 2244 is expressed as SiₓN_{y}, an ‘x/y’ value of the eighth silicon nitride film 2244 may be greater than 0.75. In addition, when each of the silicon nitride films 2230 to 2244 is expressed as SiₓN_{y}, an ‘x/y’ average value of the silicon nitride films 2230 to 2244 may be greater than 0.75. In an embodiment, for example, the ‘x/y’ average value of the silicon nitride films 2230 to 2244 may be about 0.8 or greater and about 3.0 or less.

According to an embodiment, a nitrogen content of the first silicon nitride film 2230 may be relatively lower than those of the other silicon nitride films 2232 to 2244, and a silicon content of the first silicon nitride film 2230 may be relatively higher than those of the other silicon nitride films 2232 to 2244. As a result, an atomic arrangement of the first silicon nitride film 2230 may be similar to an atomic arrangement of the silicon wafer used as the substrate 2002, and accordingly, interfacial residual stress between the first silicon nitride film 2230 and the substrate 2002 may be significantly reduced. As a result, the warpage of the deposition mask 2000 may be substantially reduced or effectively prevented.

In an embodiment, the inorganic film 2010 may be formed on a front surface of the substrate 2002, and a rear inorganic film 2300 may be formed on a rear surface of the substrate 2002. In an embodiment, for example, the inorganic film 2010 and the rear inorganic film 2300 may be formed simultaneously through the TCVD process, and accordingly, the inorganic film 2010 and the rear inorganic film 2300 may include or be made of the same material. In addition, the rear inorganic film 2300 may have a stacked structure of silicon-rich silicon nitride films, like the inorganic film 2010.

As described above, after the inorganic film 2010 and the rear inorganic film 2300 are formed on the front surface and the rear surface of the substrate 2002, respectively, pixel openings 2210 exposing the substrate 2002 may be formed by patterning the inorganic film 2010. Subsequently, cell openings 2102 that are connected to or in communication with the pixel openings 2210 may be formed by patterning the substrate 2002. In such an embodiment, processes of forming the pixel openings 2210 and the cell openings 2102 are substantially the same as those described above with reference to FIGS. 17 to 21, and any repetitive detailed description thereof is thus omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask frame with a cell opening defined therein; and
a membrane disposed on the mask frame,
wherein the membrane includes a cell region disposed on the cell opening,
a plurality of pixel openings is defined through the cell region to be connected to the cell opening, and
an interfacial residual stress between the mask frame and the membrane is in a range of about −30 MPa to about 30 MPa.

2. The deposition mask of claim 1, wherein
the mask frame includes silicon, and
the membrane includes silicon nitride.

3. The deposition mask of claim 2, wherein the membrane has a silicon content higher than a silicon content of stoichiometric silicon nitride.

4. The deposition mask of claim 2, wherein a nitrogen content of the membrane is constant in a thickness direction of the membrane.

5. The deposition mask of claim 2, wherein a nitrogen content of the membrane gradually increases from an interface between the mask frame and the membrane in a thickness direction of the membrane.

6. The deposition mask of claim 1, wherein the membrane includes a plurality of silicon nitride films stacked on the mask frame.

7. The deposition mask of claim 6, wherein a nitrogen content of the silicon nitride films stepwise increases from an interface between the mask frame and the membrane in a direction in which the silicon nitride films are stacked.

8. The deposition mask of claim 6, wherein a silicon content of the silicon nitride films stepwise decreases from an interface between the mask frame and the membrane in a direction in which the silicon nitride films are stacked.

9. The deposition mask of claim 8, wherein an uppermost silicon nitride film of the silicon nitride films has a silicon content higher than a silicon content of stoichiometric silicon nitride.

10. A method of manufacturing a deposition mask, the method comprising:
forming an inorganic film on a substrate;
forming a plurality of pixel openings by patterning the inorganic film, wherein the pixel openings exposes the substrate; and
forming cell openings by patterning the substrate, wherein the cell openings is connected to the pixel openings,
wherein an interfacial residual stress between the substrate and the inorganic film is in a range of about −30 MPa to about 30 MPa.

11. The method of claim 10, wherein the substrate includes silicon, and
the inorganic film includes silicon nitride and is formed through a chemical vapor deposition process.

12. The method of claim 11, wherein the chemical vapor deposition process is performed under a pressure in a range of about 210 mTorr to about 250 mTorr and a temperature in a range of about 800° C. to about 850° C.

13. The method of claim 11, wherein the inorganic film is formed by a reaction between a first source gas including silicon and a second source gas including nitrogen, and
a supply flow rate ratio between the first source gas and the second source gas is controlled to be in a range of about 10:1 to about 10:1.7.

14. The method of claim 13, wherein the inorganic film has a silicon content higher than a silicon content of stoichiometric silicon nitride, and
a nitrogen content of the inorganic film is constant in a thickness direction of the inorganic film.

15. The method of claim 13, wherein the supply flow rate ratio between the first source gas and the second source gas is gradually changed from about 10:1 to about 10:1.7 during the chemical vapor deposition process.

16. The method of claim 15, wherein a silicon content of the inorganic film gradually decreases from an interface between the substrate and the inorganic film in a thickness direction of the inorganic film, and
a nitrogen content of the inorganic film gradually increases from the interface between the substrate and the inorganic film in the thickness direction of the inorganic film.

17. The method of claim 13, wherein the inorganic film includes a plurality of silicon nitride films stacked on the substrate, and
the silicon nitride films are formed by stepwise changing the supply flow rate ratio between the first source gas and the second source gas from about 10:1 to about 10:1.7 during the chemical vapor deposition process.

18. The method of claim 17, wherein a silicon content of the silicon nitride films stepwise decreases from an interface between the substrate and the inorganic film in a direction in which the silicon nitride films are stacked, and
a nitrogen content of the silicon nitride films stepwise increases from the interface between the substrate and the inorganic film in the direction in which the silicon nitride films are stacked.

19. The method of claim 18, wherein an uppermost silicon nitride film of the silicon nitride films has a silicon content higher than a silicon content of stoichiometric silicon nitride.

20. An electronic device comprising a display panel comprising a substrate and a plurality of light-emitting layers disposed on the substrate,
wherein the light-emitting layers are formed by using a deposition mask comprising:
a mask frame with a cell opening defined therein; and
a membrane disposed on the mask frame,
wherein the membrane includes a cell region disposed on the cell opening,
a plurality of pixel openings is defined in the cell region to be connected to the cell opening, and
an interfacial residual stress between the mask frame and the membrane is in a range of about −30 MPa to about 30 MPa.
